(19) United States
(12) Patent Application Publication
(10) Pub. No.: US 2006/0154423 A1
(43) Pub. Date: Jul. 13, 2006

(54) Methods of forming structure and spacer and related finfet

(76) Inventors: David M. Fried, Brewster, NY (US); Edward J Nowak, Junction, VT (US); Beth Ann Rainey, Williston, VT (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(21) Appl. No.: 10/538,911

(22) PCT Filed: Dec. 19, 2002
(86) PCT No.: PCT/US02/40869

§ 371 Date: Jun. 14, 2005

(51) Int. Cl. H01L 21/336

(52) U.S. Cl. 438/283; 438/286

(57) ABSTRACT

Methods for forming a spacer (44) for a first structure (24, 124), such as a gate structure of a FinFET, and at most a portion of a second structure (14), such as a fin, without detrimentally altering the second structure. The methods generate a first structure (24) having a top portion (30, 130) that overhangs an electrically conductive lower portion (32, 132) and a spacer (44) under the overhang (40, 140). The overhang (40, 140) may be removed after spacer processing. Relative to a FinFET, the overhang protects parts of the fin (14) such as regions adjacent and under the gate structure (24, 124), and allows for exposing sidewalls of the fin (14) to other processing such as selective silicon growth and implantation. As a result, the methods allow sizing of the fin (14) and construction of the gate structure (24, 124) and spacer without detrimentally altering (e.g., eroding by forming a spacer thereon) the fin (14) during spacer processing. A FinFET (100) including a gate structure (24, 124) and spacer (44) is also disclosed.

### TECHNICAL FIELD

The present invention relates generally to CMOS processing.

### BACKGROUND ART

Spacers are common structures in complementary metal-oxide semiconductor (CMOS) processing provided to protect one structure from processing done to an adjacent structure. Exemplary types of CMOS devices in which protective spacers must be used are Fin Field Effect Transistors (FinFETs) and MesaFETs. A FinFET, for example, structurally includes, among other things, a gate that extends over and along a portion of each sidewall of a thin, vertical, silicon “fin.” In FinFETS, a spacer is required for blocking implants at the gate edge and preventing silicide shorts to the gate. Conventional planar CMOS spacer processing presents a number of problems relative to the fin. In particular, conventional processing to form the spacer for the gate results in application to the fin. If conventional spacer processes are used, fin erosion during spacer etch is a potential problem. When the fin needs to be exceptionally thin, any additional etching can prevent attainment of the desired fin size. Another challenge is formation of a spacer along the gate without formation on the fin sidewalls and the top of the fin such that the part the part of the fin not adjacent to the gate can be exposed to implantation. In conventional spacer processing, a spacer formed on the gate also forms on the sidewalls of the fin due to the three-dimensional nature of the FinFET. In some cases, such as during sidewall implantation or source drain extension, this sidewall spacer is undesirable. Attempts to remove the fin sidewall spacer result in removing the spacer on the gate where a spacer is needed. Similar problems exist relative to other CMOS devices such as MesaFETs.

In view of the foregoing, there is a need in the art for an improved method for forming a spacer on a first structure and at most a portion of a second structure without detrimentally altering the second structure during the spacer processing.

### DISCLOSURE OF THE INVENTION

The invention relates to methods for forming a spacer for a first structure, such as a gate structure of a FinFET, and at most a portion of a second structure, such as a region of the fin adjacent to the gate, without detrimentally altering (e.g., eroding or forming a spacer thereon) the second structure. The methods generate a first structure (gate structure) having a top portion that overhangs a lower portion and a spacer under the overhang. The overhang may be removed after spacer processing. The overhang protects the first structure and may protect parts of the second structure if the first structure overlaps the second structure. An example of this is a fin region adjacent and under the gate structure in a FinFET protected by a spacer, where the sidewalls of the fin are exposed to other processing such as selective silicon growth and implantation. As a result, the methods allow sizing of the second structure and construction of the first structure and spacer without detrimentally altering the second structure during spacer processing. The invention also relates to a FinFET including a gate structure and spacer formed by the methods.

The foregoing and other features of the invention will be apparent from the following more particular description of best modes for carrying out the invention.

### BRIEF DESCRIPTION OF DRAWINGS

The embodiments of this invention will be described in detail, with reference to the following figures, wherein like designations denote like elements, and wherein:

FIG. 1 shows a perspective view of a precursor structure of a FinFET including a fin without a gate material.

FIGS. 2-A-B show cross-sectional views of a first and second step of the methods.

FIGS. 3A-B show cross-sectional views of a third step of the methods.

FIGS. 4A-B show cross-sectional views of a fourth step according to a first embodiment of the methods.

FIGS. 5A-B show cross-sectional views of a fourth step according to a second embodiment of the methods.

FIGS. 6A-B show cross-sectional views of a fifth step of the methods.

FIGS. 7A-B show cross-sectional views of a sixth step of the methods and the resulting gate structure and associated spacer.

### BEST MODES FOR CARRYING OUT THE INVENTION

Methods for forming a first structure such as a gate structure and an associated spacer without detrimentally altering a second structure will now be described. The invention will be described relative to a FinFET application. For clarity, the gate structure is the “first structure” and the fin is the “second structure.” In the FinFET application, a spacer is formed, for the gate and on a portion of the fin adjacent the gate because the fin goes through the gate. However, it should be recognized that the methods described can be used for any device in which it is desired to form a spacer for a first structure and form a spacer for at most a portion (none at all or a portion) of a second structure, i.e., if two structures are separated by some distance, the methods would enable formation of a spacer on one structure without forming a spacer on the other structure at all. For example, the two structures may both be gates and a spacer may be desired on one of the gates but not at all on the other gate. Accordingly, the first and second structure terms may be applicable to a variety of different CMOS formations. For purposes of brevity of description, however, only the FinFET application will be described in detail. The phrase “detrimentally altering” means changed in an undesirable way. In the FinFET application, for example, spacer processing on the gate may detrimentally alter the fin by forming a spacer thereon or eroding the fin. Relative to the gate example above, “detrimentally alter” may include forming a spacer on the gate upon which a spacer is not desired.

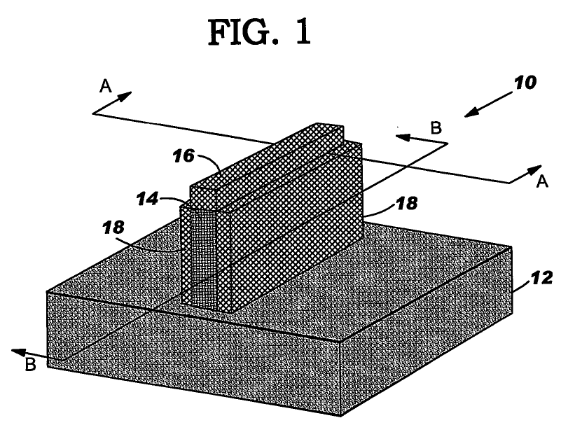

With reference to the accompanying drawings, FIG. 1 is a perspective view of a precursor structure 10 of a FinFET after gate etch. At this point in processing, structure 10 includes a substrate 12 upon which is formed a fin 14 of mono-crystalline silicon. The gate structure (not shown) will eventually be constructed over fin 14. A hardmask 16 is also provided to protect fin 14 during processing. Hardmask 16 may be, for example, silicon dioxide (oxide) or silicon nitride. Actual processing to establish this precursor structure 10 may include deposition of a hardmask 16, etching hardmask 16 and the underlying silicon to generate fin 14, conducting a sacrificial oxidation and gate oxidation of the silicon to generate structure oxide 18. It should be recognized that the above processing is simply exemplary and that other processing may also be possible to achieve the illustrated structure. Fin 14, as shown, is ready for generation of a gate structure and a spacer for the gate structure.

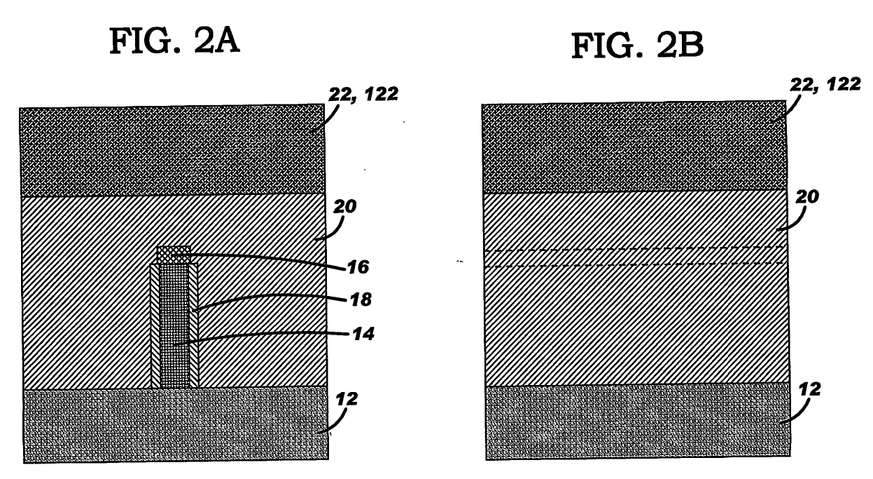

FIGS. 2-7 illustrate methods for forming a spacer for a gate and a spacer for at most a portion of a fin during the spacer processing. In the drawings, those figures labeled ‘A’ show a cross-sectional view A-A across fin 14 as shown in FIG. 1, and those labeled ‘B’ show a cross-sectional view B-B as shown in FIG. 1 (through the gate structure once formed).

In a first step, shown in FIGS. 2A-B, a first material 20 for generation of a gate structure is deposited over fin 14. FIGS. 2A-B also show a second step in which a second material 22, 122 is formed over first material 20. (Second material 22, 122 includes the dual designation because the material may be provided in two different forms, as will be described in more detail below.) As also will be described in more detail below, second material 22, 122 is different than first material 20.

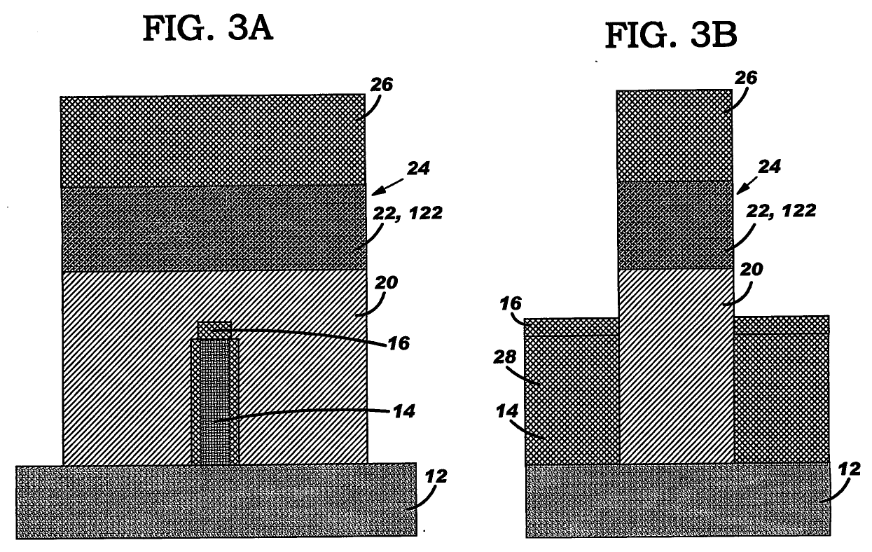

FIGS. 3A-3B show the next step in which a gate structure 24 is formed in first material 20 and second material 22, 122. Forming may include applying and patterning (e.g., with lithography) a hardmask 26, e.g., oxide (TEOS), over first material and second material 22, 122, and etching the materials to form gate structure 24. As shown in FIG. 3B, these steps are also applied to eventual source and drain regions 28 of fin 14. Subsequently, hardmask 26 is removed in a known fashion.

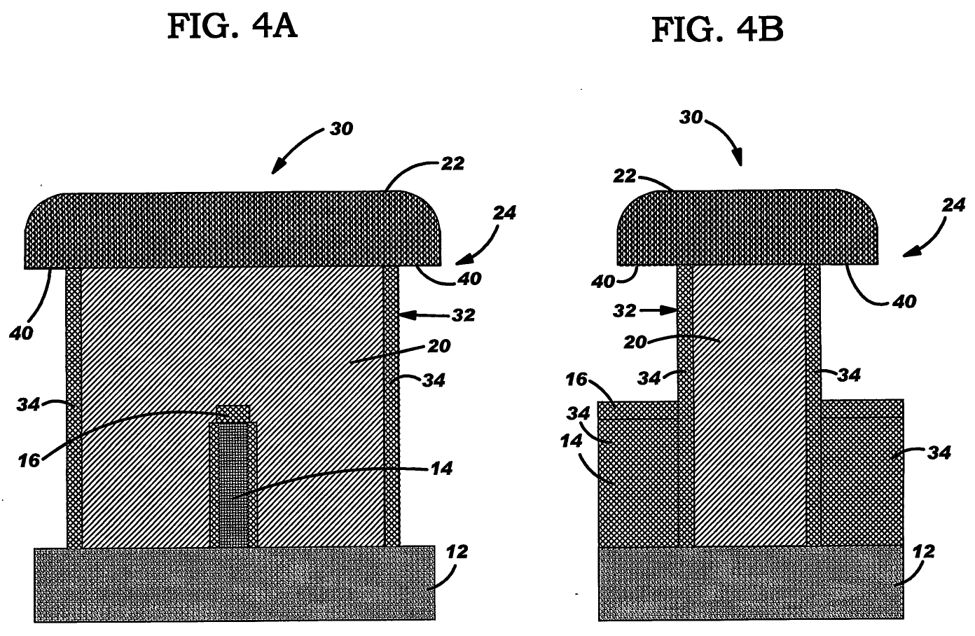

FIGS. 4A-B and 5A-B illustrate two embodiments of the next step in which second material 22, 122 is made to overhang first material 20. As noted above, second material 22, 122 is different than first material 20.

FIGS. 4A-B show a first embodiment in which second material 22 is formed (in the step shown in FIGS. 2A-B) as a polycrystalline silicon (hereinafter ‘polysilicon’) such that it has an oxidation rate faster than first material 20. In order to provide these differential oxidation rates, in one embodiment, second material 22 may be a portion of first material 20 that is implanted with a dopant in a known fashion. The dopant may be any material that causes polysilicon second material 22 to oxidize at a faster rate than non-doped polysilicon. The dopant may be, for example, Arsenic (As) (preferred), Germanium (Ge), Cesium (Cs), Argon (Ar) or Flourine (F) or a combination thereof. In another embodiment, second material 22 that has a faster oxidation rate than first material 20 may be deposited on the first material, e.g., as polycrystalline silicon-germanium alloy. First material 20 may be, for example, non-doped polysilicon. According to this embodiment, second material 22 is made to overhang first material 20 by conducting an oxidation, e.g., at 800 to 950° C. The differential oxidation rate between materials generates a thicker oxide from second material 22 of gate structure 24 relative to fin 14 and first material 20. The result is generation of an overhang 40 of fin 14 adjacent to first material 20. FIGS. 4A-B show the resulting structure in which second material 22 forms a top portion 30 of gate structure 24 that overhangs an electrically conductive lower portion 32 thereof. The oxidation process may also cause thin oxide layers 34 (e.g., approximately ten times thinner than second material 22) to form on the sides of first material 20 (i.e., lower portion 32) and the sides of fin 14 outside of gate structure 24. Oxide layer 34 allows for preservation of fin 14 width without oxidizing the fin away.

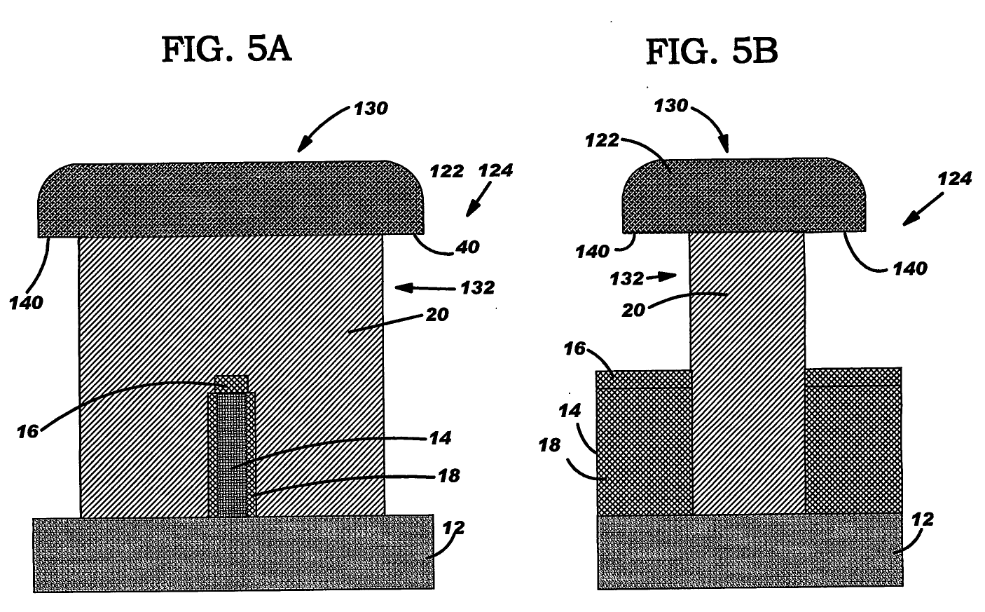

FIGS. 5A-B show a second, alternative embodiment for making second material 122 overhang first material 20. In this case, second material 122 is provided (in the step shown in FIGS. 2A-B) as any material having different thermal reflow properties than first material 20. In one embodiment, first material 20 is provided as polysilicon or a metal such as cobalt-silicide or tungsten, and second material 122 is provided as a glass such as boro-phospho-silicate glass (BPSG) or phospho-silicate glass (PSG). The step of making second material 122 overhang first material 20 then includes conducting a thermal process to cause material 122 to reflow and form an overhang 140. The thermal process may include, for example, heating at least the second material at approximately 850° C for approximately ten minutes in a non-oxidizing ambient. FIGS. 5A-B show the resulting structure in which second material 122 forms a top portion 130 of a gate structure 124 that overhangs an electrically conductive lower portion 132 thereof.

With further regard to FIGS. 4A-B and 5A-B, it should be recognized that the shapes of second materials 22, 122 as illustrated may vary depending on the embodiment used and the specific processing provided. Accordingly, while the figures illustrate a bulbous or umbrella-like shape for materials 20, 22, 122, other shapes that provide the overhang may be possible.

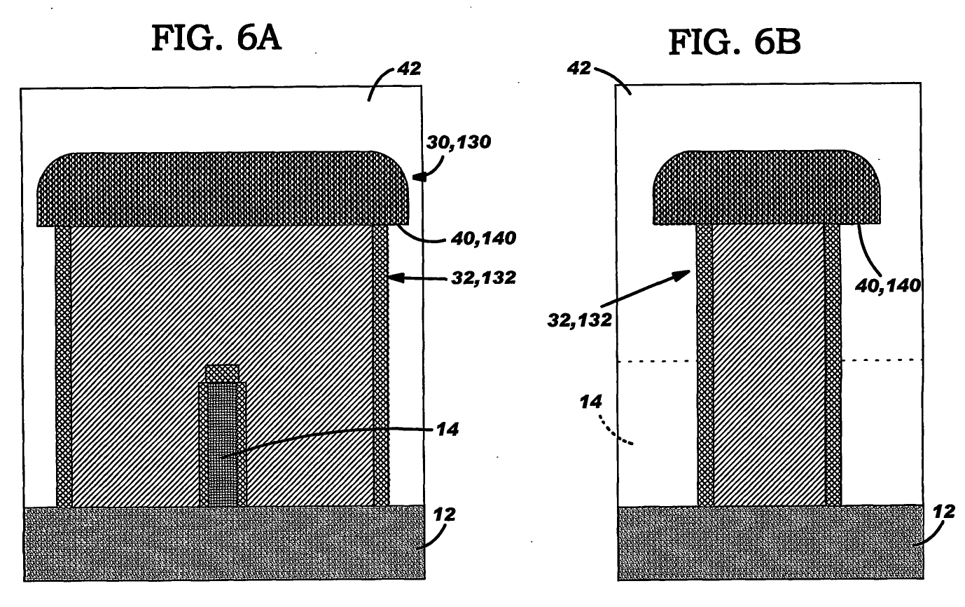

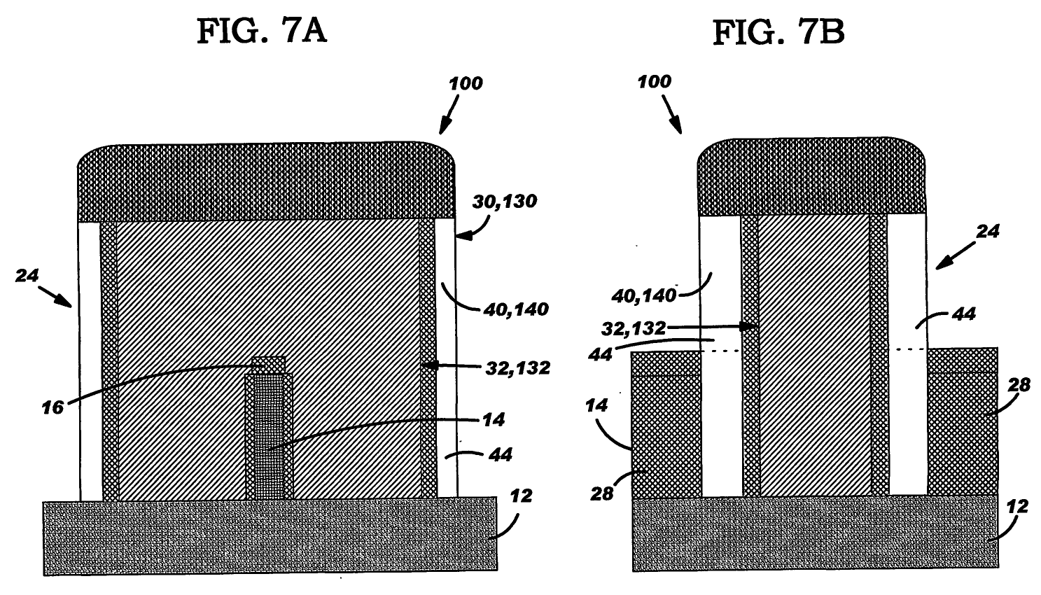

The next step includes forming a spacer under overhang 40, 140. The spacer may be formed on the structure of either embodiment above. However, FIGS. 6A-B and 7A-B show only the embodiment of FIGS. 4A-B for brevity sake. In one embodiment for forming a spacer, a spacer material 42 is conformally deposited, as shown in FIGS. 6A-B. Spacer material may be, for example, silicon nitride, silicon oxide or a combination thereof. Finally, as shown in FIGS. 7A-B, spacer material 42 is etched using a directional reactive ion etching process which removes material everywhere except under overhang 40, 140 to form a spacer 44.

Finishing processing (not shown) may follow. This processing may include, for example, removal of oxide 34 from the sides of fin 14 (oxide remains as top portion 30 if doped polysilicon used) or removal of top portion 130, i.e., the glass, from gate structure 124 (if used). In the FinFET application, final processing may include, for example, implanting to set threshold voltage (Vt), doping the source/drain regions 28 of fin 14, selective silicon growth to widen the source/drain regions 28 on fin 14, removing remaining oxide and forming cobalt-silicide (CoSi), conventional contact processing, finishing with appropriate metal levels, etc.

The resulting FinFET 100, shown in FIGS. 7A-7B, includes, among other things, a gate structure 24, 124 including an electrically conductive lower portion 32, 132 and an overhanging top portion 30, 130, a fin 14 extending through the lower portion, and a spacer 44 positioned under top portion 30, 130 of gate structure 24, 124 adjacent to conducting lower portion 32, 132. Top portion 30, 130 is made of a material (e.g., oxide or glass) that is different than the material (e.g., polysilicon) of lower portion 32, 132 as described above.

In the previous description, “gate structure” 24, 124 has been described as including a top portion 30, 130 and a lower portion 32, 132. It should be recognized, however, that top portion 30, 130 may not ultimately form an operative or active part of the actual gate used. For instance, at least a part of top portion 30, 130 and/or overhang 40, 140 may be removed to allow for contacts to be made to lower portion 32, 132 of gate structure 24, 124.

While the invention has been described in conjunction with several preferred embodiments, those skilled in the art will recognize that the invention can be practiced in various versions within the spirit and scope of the following claims.

### INDUSTRIAL APPLICABILITY

The invention is useful for forming a spacer for a gate of a FinFET, and at most a portion of a fin without detrimentally altering the fin.

1. A method for forming a spacer (44) for a first structure (24, 124) and a spacer for at most a portion of a second structure (14), the method comprising the steps of:
depositing a first material (20);
forming a second material (22, 122) over the first material;
forming the first structure from the first and second materials;
making the second material overhang (40, 140) the first material; and
forming a spacer (44) under the overhang.

2. The method of claim 1, wherein the second structure (14) is made of monocrystalline silicon, and the first material (20) is made of polycrystalline silicon.

3. The method of claim 1, wherein the second material (22) is formed such that the second material has a faster oxidation rate than the first material.

4. The method of claim 3, wherein the second material includes a dopant including at least one of the group comprising: Arsenic, Germanium, Cesium, Argon and Flourine.

5. The method of claim 3, wherein the second material is a deposited polycrystalline silicon-germanium alloy.

6. The method of claim 3, wherein the step of making includes oxidation to form the overhang as a result of a differential oxidation rate of the second material (22) with respect to the first material (20).

7. The method of claim 3, wherein the step of making includes forming oxide (34) on sides of the first structure (24) and the second structure (14).

8. The method of claim 1, wherein the second material (122) has different thermal reflow properties than the first material.

9. The method of claim 8, wherein the second material (122) is one of BPSG and PSG.

10. The method of claim 8, wherein the step of making includes heating the second material to cause the second material to reflow to form the overhang (40, 140).

11. The method of claim 1, wherein the step of forming the spacer (44) includes:
depositing a spacer material (42); and
directionally etching the spacer material away except under the overhang (40, 140).

12. The method of claim 11, wherein the spacer material (42) is at least one of silicon nitride and silicon oxide.

13. The method of claim 1, wherein the first structure (24, 124) is a gate and the second structure (14) is a fin of a FinFET (100).

14. A method for forming a gate structure (24, 124) and associated spacer (44) for a FinFET, the method comprising the steps of:
depositing a first gate material (20) over a fin of the FinFET;
forming a second material (22, 122) over the gate material, wherein the second material has a faster oxidation rate than the gate material;
forming the gate structure into the gate material and the second material;
oxidizing to cause the second material to overhang (40) the gate material; and
forming a spacer (44) under the overhang.

15. The method of claim 14, wherein the fin (14) is made of monocrystalline silicon and the gate material (20) is polycrystalline silicon.

16. The method of claim 14, wherein the second material (22) is a polycrystalline silicon formed such that the second material has a faster oxidation rate than the first material.

17. The method of claim 14, wherein the step of oxidizing also forms oxide (34) on sides of the structure (14) and gate (24).

18. The method of claim 14, wherein the step of forming the spacer (44) includes:
depositing a spacer material (42); and
etching the spacer material away except under the overhang (40).

19. A FinFET comprising:
a gate structure (24, 124) including an electrically conductive lower portion (32, 132) and an overhanging top portion (30,. 130);
a fin (14) extending through the lower portion; and
a spacer (44) positioned under the top portion of the gate structure adjacent to the lower portion.

20. The FinFET of claim 19, wherein the top portion (30, 130) is made of one of oxide and glass, and the lower portion (32, 132) is made of polycrystalline silicon.

21. The FinFET of claim 19, wherein the spacer (44) surrounds the lower portion (32, 132) and portions of the fin (14) adjacent the gate (24, 124).
